(19) United States
(12) Patent Application Publication
(10) Pub. No.: US 2025/0029953 A1
(43) Pub. Date: Jan. 23, 2025

(54) Inter-Terminal Die-to-Die Attachment

(71) Applicant: Murata Manufacturing Co., Ltd., Kyoto (JP)

(72) Inventor: Kazunori Tsuda, Cambridge, MA (US)

(21) Appl. No.: 18/353,671

(22) Filed: Jul. 17, 2023

(51) Int. Cl. H01L 25/065; H01L 23/00

(52) U.S. Cl. CPC H01L 25/0657; H01L 24/08; H01L 24/16; H01L 24/81; H01L 2224/08146; H01L 2224/16145; H01L 2224/16225; H01L 2224/80895; H01L 2224/81815; H01L 2225/06513; H01L 2225/06517; H01L 2225/06541; H01L 2924/19011

(57) ABSTRACT

Integrated circuit (IC) packaging concepts that include the attachment of an auxiliary die to a primary die between the terminals of the primary die. The auxiliary die may include one or more capacitors and/or inductors as well as active circuitry (including, for example, vertical FETs). In some embodiments, more than one auxiliary IC may be attached (directly or indirectly) to a primary IC. Such a multiple IC stack configuration reduces parasitic capacitance and/or inductance compared to conventional side-by-side arrangements, and thus enables higher frequency operation. In power converters, higher operation frequency generally allows a beneficial tradeoff between reducing the capacitance requirement and/or the inductance requirement (if present) for the circuit, and generally improves the energy transfer capability of the power converter.

### BACKGROUND

### (1) Technical Field

The present invention relates to three-dimensional integrated circuit packaging structures.

### (2) Background

The electronics industry continues to strive for ever-increasing electronic functionality and performance in a wide variety of products, including (by way of example only) personal electronics (e.g., “smart” watches and fitness wearables), personal computers, tablet computers, wireless network components, televisions, cable system “set top” boxes, radar systems, and cellular telephones. A concurrent trend is the desire to package such increased functionality and/or performance into smaller sizes. The two-dimensional (2-D) planar form-factor or “footprint” of circuit modules and circuit boards is one constraint on reducing the size of electronic products.

Reducing the size of circuit modules and circuit boards is often hampered by the need to accommodate relatively large passive components, such as capacitors and inductors. For example, physically large capacitors and inductors may be needed for power converters, particularly charge-pump type power converters.

Accordingly, many capacitors and inductors are discrete components that are directly mounted on the surface of or within a module substrate or printed circuit board (PCB) near packaged IC chips. A module substrate in turn is often electrically connected to another structure, such as a PCB, which may host multiple module substrates as well as other components. As should be apparent, mounting capacitors and inductors to a module substrate consumes planar area, thus constraining reduction of the size of a module substrate. Further, placement of capacitors and inductors at a distance from a packaged IC increases undesirable impedances and parasitic capacitances and inductances, a problem that is exacerbated as operational frequencies increase.

A variety of techniques exist for forming “on-chip” capacitors and inductors fully integrated with CMOS IC chips. For example, on-chip capacitors may be made using MIM (metal-insulator-metal), MOM (metal-oxide-metal), and MOS (metal-oxide-semiconductor) processes. However, many applications require high capacitance densities that such on-chip capacitor techniques cannot achieve for IC dies of a few square millimeters in size at most. For example, current MIM, MOM, and MOS on-chip capacitor techniques deliver capacitance densities measured in a few pico-Farads per square millimeter (pF/mm²) at most, unless expensive and time-consuming (months of fab time) multiple laminations are used (and even then, capacitance density is still relatively low). In contrast, in many applications, particularly power converters, capacitance densities need to be measured in micro-Farads per square millimeter (pF/mm²)—that is, about 1,000,000 times greater capacitance than on-chip capacitors can provide. A similar problem applies to on-chip inductors. For example, on-chip planar spiral inductors provide limited inductance due to a restricted number of turns possible and also suffer a low Quality (Q) factor while simultaneously requiring relatively large amounts of silicon surface area.

Achieving high capacitance and inductance values using current on-chip techniques requires very large IC dies, which is the antithesis of modern design goals. Accordingly, circuit designs requiring high capacitance and/or inductance values typically use discrete capacitors (e.g., silicon capacitors) and inductors as described above, thereby consuming planar area of a mounting structure (e.g., a module substrate or a PCB). The discrete capacitors and inductors are often packaged as surface mount devices (SMDs) to make handling easy during PCB fabrication.

Accordingly, there exists a need in the art for an IC packaging solution having much higher capacitance and/or inductance densities than are achievable with current on-chip solutions and which reduces consumption of planar area of a mounting structure. The present invention addresses this need.

### SUMMARY

The present invention encompasses IC packaging concepts that include the attachment of an auxiliary die to a primary die between the terminals of the primary die. The auxiliary die may include one or more capacitors and/or inductors as well as active circuitry (including, for example, vertical FETs). In some embodiments, more than one auxiliary IC may be attached (directly or indirectly) to a primary IC.

Such a multiple IC stack configuration reduces parasitic capacitance and/or inductance compared to conventional side-by-side arrangements, and thus enables higher frequency operation. In power converters, higher operation frequency generally allows a beneficial tradeoff between reducing the capacitance requirement and/or the inductance requirement (if present) for the circuit, and generally improves the energy transfer capability of the power converter.

The invention encompasses a multiple integrated circuit (IC) stack, including a primary IC configured with a primary array of terminals; and a first auxiliary IC configured with a first auxiliary array of terminals and electrically connected to the primary IC through at least one terminal of the first auxiliary array of terminals, wherein the first auxiliary IC is positioned within a void region of the primary IC lacking terminals within the primary array of terminals.

The invention also encompasses a method of making a multiple integrated circuit (IC) stack, including: configuring a primary IC with a primary array of terminals; configuring a first auxiliary IC with a first auxiliary array of terminals; positioning the first auxiliary IC within a void region of the primary IC lacking terminals within the primary array of terminals; and electrically connecting the first auxiliary IC to the primary IC through at least one terminal of the first auxiliary array of terminals

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a cross-sectional view of a stylized prior art MOSFET.

FIG. 1B is a cross-sectional view of a stylized prior art MOSFET formed by an SLT process.

FIG. 2A is a bottom plan view of a prior art packaged IC comprising an IC configured with an array of terminals in the form of solder bumps, solder balls, copper pillars, or the like.

FIG. 2B is a cross-sectional view of FIG. 2A taken along line A-A.

FIG. 3A is a bottom plan view of a multiple IC stack in accordance with the present invention.

FIG. 3B is a cross-sectional view of FIG. 3A taken along line B-B.

FIG. 3C is a cross-sectional view of a multiple IC stack that includes an auxiliary IC having an RDL.

FIG. 4 is a bottom plan view of a multiple IC stack having multiple rectangular auxiliary ICs of different sizes positioned between the terminals of a primary IC.

FIG. 5A is a bottom plan view of a multiple IC stack having two rectangular auxiliary ICs positioned between the terminals of a primary IC.

FIG. 5B is a bottom plan view of a multiple IC stack having two rectangular auxiliary ICs positioned between the terminals of a primary IC rotated at about a 45° angle with respect to the grid pattern of the primary array of terminals.

FIG. 6 is a bottom plan view of a multiple IC stack having two rectangular auxiliary ICs positioned between different sets of terminals of a primary IC rotated at about a 33° angle with respect to the grid pattern of the primary array of terminals.

FIG. 7 is a bottom plan view of a multiple IC stack having an auxiliary IC positioned between a set of terminals of a primary IC.

FIG. 8A is a bottom plan view of a first example multiple IC stack that includes a sub-stack comprising multiple auxiliary ICs.

FIG. 8B is a cross-sectional view of a first embodiment of FIG. 8A taken along line C-C.

FIG. 8C is a cross-sectional view of a second embodiment of FIG. 8A taken along line C-C.

FIG. 9A is a bottom plan view of a second example multiple IC stack that includes a sub-stack comprising multiple auxiliary ICs.

FIG. 9B is a cross-sectional view of FIG. 9A taken along line D-D.

FIG. 10 is a schematic diagram of a prior art 3-level DC-to-DC buck converter circuit.

FIG. 11 is a bottom plan view of a first multiple IC stack with a stylized schematic circuit overlay representing in part the circuit of FIG. 10.

FIG. 12 is a bottom plan view of a second multiple IC stack with a stylized schematic circuit overlay representing in part the circuit of FIG. 10.

FIG. 13 is a top plan view of a substrate that may be, for example, a printed circuit board or chip module substrate (e.g., a thin-film tile).

FIG. 14 is a process flow chart showing one method for making a multiple IC stack.

Like reference numbers and designations in the various drawings indicate like elements.

### DETAILED DESCRIPTION

The present invention encompasses IC packaging concepts that include the attachment of an auxiliary die to a primary die between the terminals of the primary die. The auxiliary die may include one or more capacitors and/or inductors as well as active circuitry (including, for example, vertical FETs). In some embodiments, more than one auxiliary IC may be attached (directly or indirectly) to a primary IC.

Such a multiple IC stack configuration reduces parasitic capacitance and/or inductance compared to conventional side-by-side arrangements, and thus enables higher frequency operation. In power converters, higher operation frequency generally allows a beneficial tradeoff between reducing the capacitance requirement and/or the inductance requirement (if present) for the circuit, and generally improves the energy transfer capability of the power converter.

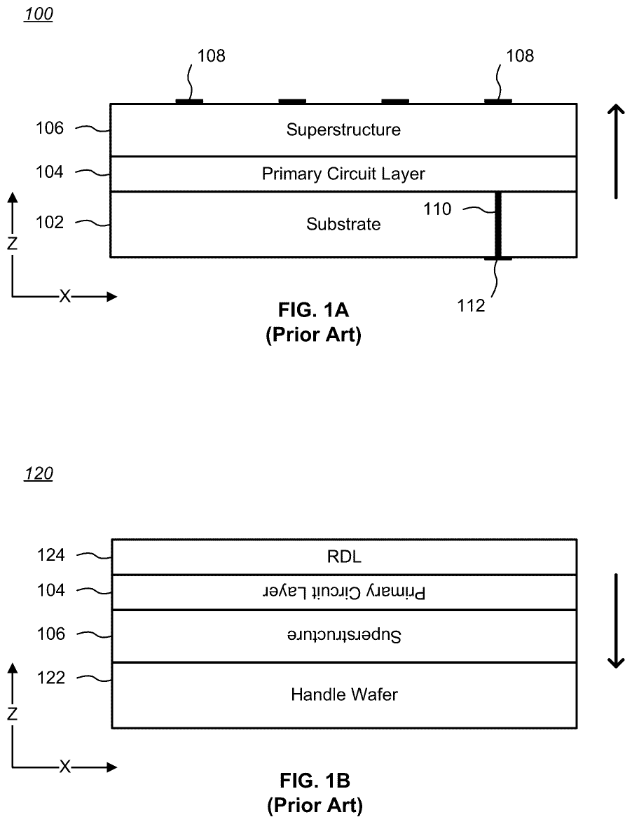

It may be useful to review how a metal-oxide-semiconductor field-effect transistor (MOSFET) circuitry is fabricated. FIG. 1A is a cross-sectional view of a stylized prior art MOSFET 100. Starting with a wafer substrate 102, such as silicon, a primary circuit layer 104 is formed, typically of doped silicon. For silicon-on-insulator (SOI) MOSFET's, an insulating buried oxide (BOX) layer (not shown) may be formed on the wafer substrate 102 before forming the primary circuit layer 104.

On and/or within the primary circuit layer 104, one or more MOSFET structures (not shown) are formed within the bounds of an individual IC die (unsingulated at this point). Each wafer substrate typically includes hundreds to thousands of unsingulated dies.

A MOSFET structure generally includes a mask-formed channel, a gate, a source, a drain, and isolation regions. The IC fabrication process up to this point is generally considered the front-end-of-line (FEOL) where individual devices (transistors, capacitors, resistors, inductors etc.) are patterned in or on the primary circuit layer 104. The FEOL generally covers everything up to (but not including) the deposition of metal interconnect layers, and may be regarded as fabrication of die substructures.

After the last FEOL step, a wafer contains multiple die regions each including isolated transistors without any interconnecting conductors. The back-end-of-line (BEOL) is the second portion of IC fabrication where the individual devices (transistors, capacitors, resistors, inductors, etc.) within a die region are interconnected with conductors formed as part of or spanning one or more metal interconnect layers. BEOL includes fabrication of a superstructure 106 that includes, for example, vias, insulating layers (dielectrics), metallization layers, and electrical contacts (pads) 108 for die-to-package connections. In some applications, one or more “through-substrate vias” (TSVs) 110 may be fabricated, each TSV passing through the wafer substrate 102 between the primary circuit layer 104 and an electrical connection point 112, such as a bonding pad.

Some BEOL fabrication processes or post-BEOL fabrication processes (e.g., as part of Outsourced Semiconductor Assembly and Test, or “OSAT”) allow application of a redistribution layer (RDL), which is generally an extra patterned conductive layer (commonly aluminum) on an IC die that makes the input/output (I/O) pads of an IC die available to be coupled to other locations of the die, and/or to another IC die, and/or to specialized packaging structures. The RDL may be formed on top of the “upper” BEOL superstructure of an IC die. In some cases (for example, for single-layer transfer or SLT die structures), the RDL may be formed adjacent to a primary circuit layer containing active MOSFET regions after removal of the wafer substrate and re-attachment of the primary circuit layer and superstructure to a handle wafer.

For example, FIG. 1B is a cross-sectional view of a stylized prior art MOSFET 120 formed by an SLT process. An IC die similar to MOSFET 100 of FIG. 1A is essentially inverted (compare arrow in FIG. 1A to arrow in FIG. 1B), such that the superstructure 106 can be bonded to a handle wafer 122. The initial substrate 102 is partially or fully removed, and an RDL 124 formed adjacent to the primary circuit layer 124.

Thus, a MOSFET IC die is essentially formed in two parts, a “lower” FEOL substructure that includes the primary circuit layer 124, and an “upper” BEOL superstructure. After FEOL and BEOL processing, the wafer may undergo a number of additional process steps, including dicing and testing, to form multiple IC dies.

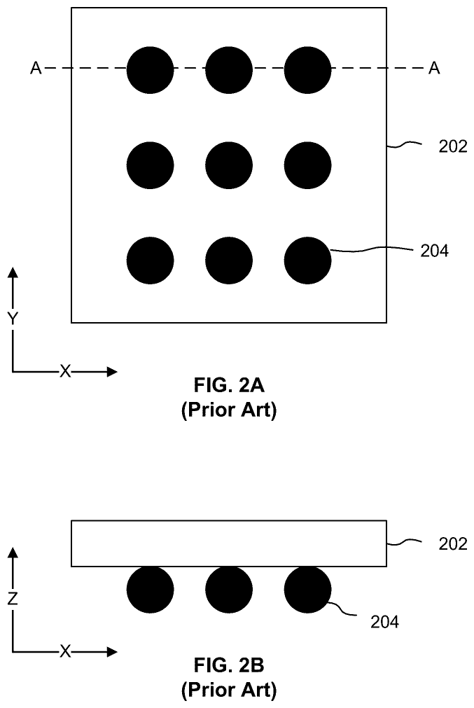

One or more IC dies may be configured to be attached to a chip module substrate (e.g., a thin-film tile or other chip carrier), which in turn may be configured to be attached to yet further structures, such as a printed circuit board. For example, FIG. 2A is a bottom plan view of a prior art packaged IC 200 comprising an IC 202 configured with an array of terminals 204 in the form of solder bumps, solder balls, copper pillars, or the like. FIG. 2B is a cross-sectional view of FIG. 2A taken along line A-A. While a square 3×3 array of terminals 204 is illustrated, the array may be of other dimensions and need not be square. A common example of such an array is a ball grid array (BGA), in which the IC 202 is configured with electrically conductive (e.g., copper) pads on one side of the IC structure and each pad initially has a tiny solder ball stuck to it. The solder spheres can be placed manually or by automated equipment, and may be held in place with a tacky flux. The packaged IC 200 may be placed on a PCB with electrically conductive pads in a pattern that matches the solder balls. The assembly is then heated, either in a reflow oven or by an infrared heater, melting the solder balls. Surface tension causes the molten solder to hold the package in alignment with the PCB, at the correct separation distance, while the solder cools and solidifies, forming soldered connections between the device and the PCB.

Conventionally, a packaged IC 200 requiring a large capacitance and/or inductance would be placed on a PCB or the like adjacent to a packaged capacitor or inductor. As noted above, mounting capacitors and inductors to a module substrate in such a “side-by-side” arrangement consumes planar area, thus constraining reduction of the size of a module substrate.

One aspect of the present invention is the attachment of an auxiliary die to a primary die between the terminals of the primary die, where the auxiliary die includes one or more capacitors and/or inductors. Such a stacked configuration reduces parasitic capacitance and/or inductance compared to conventional side-by-side arrangements, and thus enables higher frequency operation. In power converters, higher operation frequency generally allows a beneficial tradeoff between reducing the capacitance requirement and/or the inductance requirement (if present) for the circuit, and improves the energy transfer capability of the power converter.

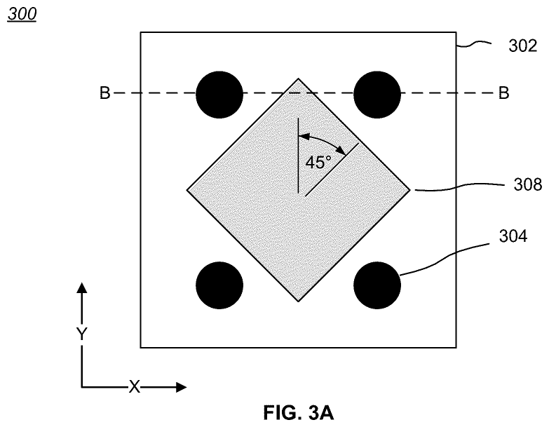

FIG. 3A is a bottom plan view of a multiple IC stack 300 in accordance with the present invention. FIG. 3B is a cross-sectional view of FIG. 3A taken along line B-B. The multiple IC stack 300 includes a primary IC 302 configured with a primary array of terminals 304 in the form of solder bumps, solder balls, copper pillars, or the like. The primary IC 302 may be, for example, a power converter or a radio frequency (RF) circuit. Electrically and/or thermally connected to the primary IC 302 through an auxiliary array of terminals 306 is an auxiliary IC 308, such as a silicon capacitor. The auxiliary array of terminals 306 may be formed in the same manner as the primary array of terminals 304, but smaller in size, such that the “Z” height of the auxiliary array of terminals 306 and the auxiliary IC 308 is less than the post-reflow “Z” height of the primary array of terminals 304.

The auxiliary IC 308 may be indirectly connected electrically and/or thermally to a PCB 310 through the auxiliary array of terminals 306 to the primary IC 302 and thence through the primary array of terminals 304. In alternative embodiments, the backside of the auxiliary IC 308 (the side facing away from the primary IC 302) may include electrical contacts formed in a redistribution layer that allow direct connection between the auxiliary IC 308 and a PCB. For example, FIG. 3C is a cross-sectional view of a multiple IC stack 320 that includes an auxiliary IC 308 having an RDL 312. Portions of the RDL 312 may be configured to directly connect to a PCB substrate electrically and/or thermally (e.g., to spread heat from either or both of the primary IC 302 and the auxiliary IC 308). In some embodiments, an additional array of terminals 314 may be formed on the RDL 312 and configured to electrically and/or thermally connect to a PCB substrate (not shown to avoid clutter, but see FIG. 3B). The finer pitch of RDL routing (less than about 20 μm in current processes) compared to PCB routing (typically about 50-100 μm with current processes) provides greater flexibility in component layout and connections.

One constraint on the “Z” height of the auxiliary array of terminals 306, the auxiliary IC 308 with RDL 312, and optional additional array of terminals 314 is that their total stacked height should be the same as the post-reflow “Z” height of the primary array of terminals 304 in order for the connections to the backside of the auxiliary IC 308 to be in contact with the PCB substrate once the primary array of terminals 304 melt.

As FIG. 3A illustrates, the auxiliary IC 308 is positioned within a void region of the primary IC 302 lacking terminals within the primary array of terminals 304. A preferred position of the auxiliary IC 308 is rotated at about a 45° angle with respect to the grid pattern of the primary array of terminals 304. However, other angles may be used, as well as other shapes and numbers of the auxiliary IC 308. There is some advantage to keeping the rotation angle between about 30° and 60° in that the size of the auxiliary IC 308 can generally be maximized while providing a suitable spacing away from the primary array of terminals 304.

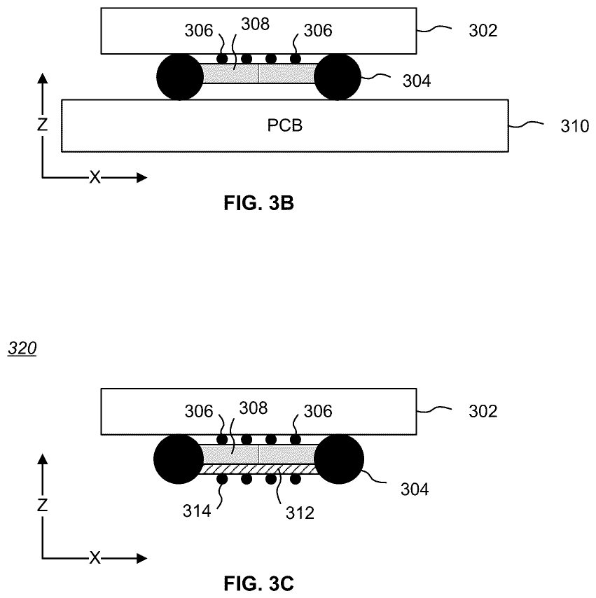

For example, FIG. 4 is a bottom plan view of a multiple IC stack 400 having multiple rectangular auxiliary ICs 308a-308c of different sizes positioned between the terminals 304 of a primary IC 302; each of the auxiliary ICs 308a-308c would have a corresponding auxiliary array of terminals (not shown in FIG. 4).

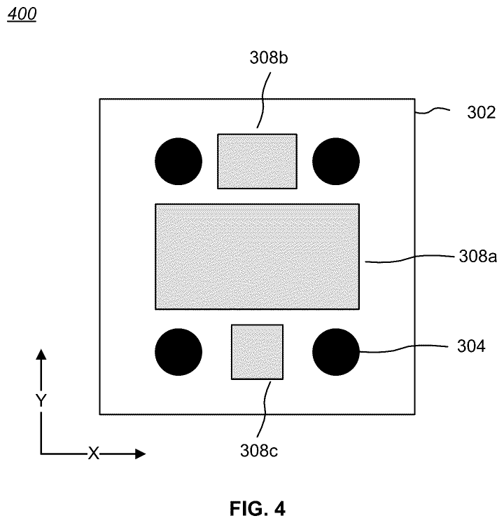

FIG. 5A is a bottom plan view of a multiple IC stack 500 having two rectangular auxiliary ICs 308a-308b positioned between the terminals 304 of a primary IC 302. FIG. 5B is a bottom plan view of a multiple IC stack 520 having two rectangular auxiliary ICs 308a-308b positioned between the terminals 304 of a primary IC 302 rotated at about a 45° angle with respect to the grid pattern of the primary array of terminals 304.

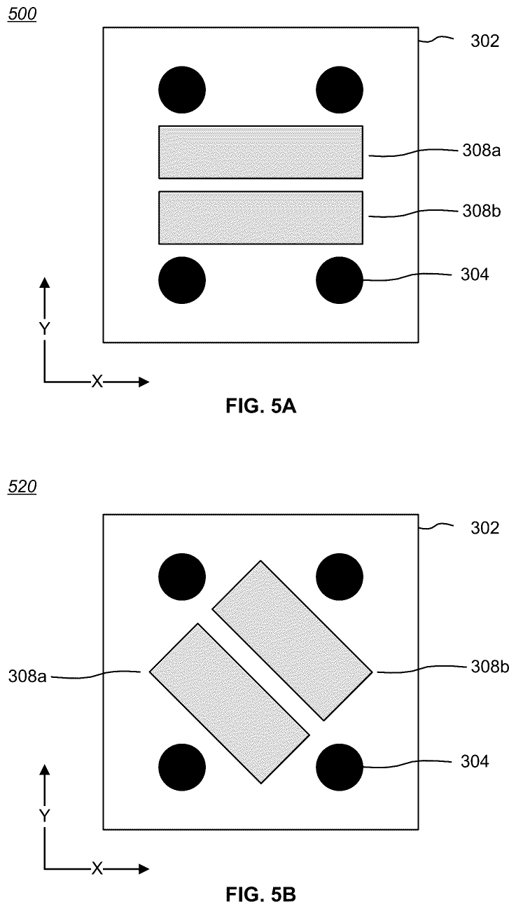

FIG. 6 is a bottom plan view of a multiple IC stack 600 having two rectangular auxiliary ICs 308a-308b positioned between different sets of terminals 304 of a primary IC 302 rotated at about a 33° angle with respect to the grid pattern of the primary array of terminals 304.

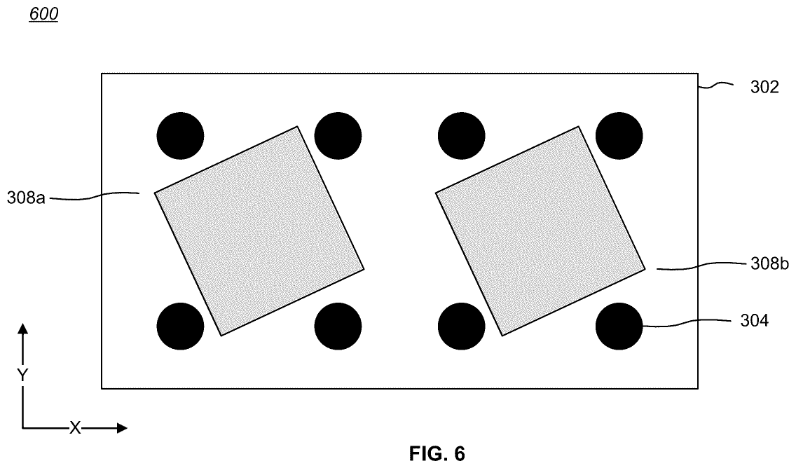

FIG. 7 is a bottom plan view of a multiple IC stack 600 having an auxiliary IC 308 positioned between a set of terminals 304 of a primary IC 302. This view shows that an auxiliary IC 308 may occupy only a relatively small portion of the attachment surface of a primary IC 302, with the remaining portion of the attachment surface available for terminals 304.

Another aspect of the invention is that multiple auxiliary ICs 308 may be stacked on each other, optionally with direct electrical and/or thermal connections between the members of the stack, and optionally with the “bottom-most” member of the stack having a redistribution layer and an array of terminals configured to electrically and/or thermally connect to a PCB substrate or the like.

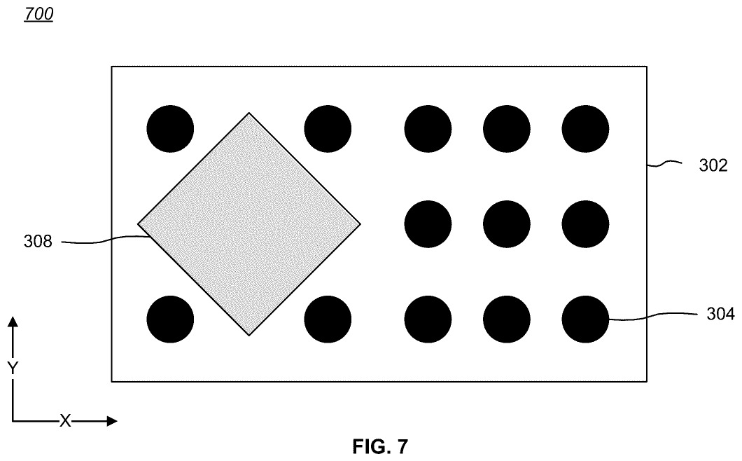

For example, FIG. 8A is a bottom plan view of a first example multiple IC stack 800 that includes a sub-stack comprising multiple auxiliary ICs 308a-308b in stacked proximity. FIG. 8B is a cross-sectional view of a first embodiment of FIG. 8A taken along line C-C. FIG. 8C is a cross-sectional view of a second embodiment of FIG. 8A taken along line C-C.

In a first embodiment, a first auxiliary IC 308a is attached to a primary IC 302 within a void region of the primary IC 302 lacking terminals within the primary array of terminals 304, as described above. A second auxiliary IC 308b is then attached to the first auxiliary IC 308a, as shown in FIG. 4B. The attachment of the auxiliary ICs 308a, 308b may be, for example, by direct die-to-die hybrid bonding, with interconnecting electrical connections made, for example, by TSVs 802, RDL pads, or a combination of TSVs and RDL pads. In some embodiments, the first and second auxiliary ICs 308a, 308b are bonded together as a stack before the stack is attached as a unit to the primary IC 302 through an auxiliary array of terminals 306.

In a second embodiment, a first auxiliary IC 308a is attached to a primary IC 302 within a void region of the primary IC 302 lacking terminals within the primary array of terminals 304, as described above. A second auxiliary IC 308b is then attached to the first auxiliary IC 308a through an intervening array of terminals 804 in the form of solder bumps, solder balls, copper pillars, or the like, as shown in FIG. 4C. In some embodiments, the first and second auxiliary ICs 308a, 308b are coupled together as a stack before the stack is attached as a unit to the primary IC 302.

While FIG. 8A shows the second auxiliary IC 308b as being smaller than the first auxiliary IC 308a, the two auxiliary ICs may be of the same size, or the second auxiliary IC 308b may be larger than the first auxiliary IC 308a.

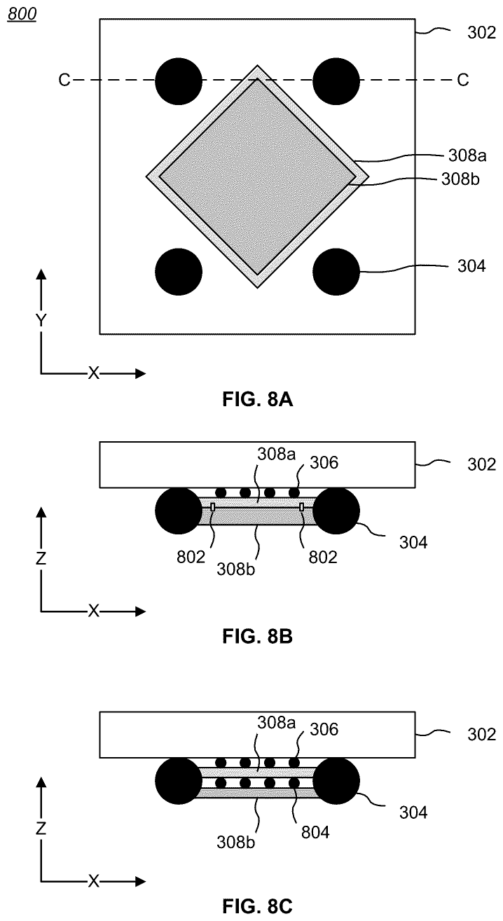

As another example, FIG. 9A is a bottom plan view of a second example multiple IC stack 900 that includes a sub-stack comprising multiple auxiliary ICs 308a-308b. FIG. 9B is a cross-sectional view of FIG. 9A taken along line D-D. A first auxiliary IC 308a is attached to a primary IC 302 within a void region of the primary IC 302 lacking terminals within the primary array of terminals 304, as described above. A second auxiliary IC 308b is then attached to the primary IC 302 through an intervening array of terminals 902 in the form of solder bumps, solder balls, copper pillars, or the like, as shown in FIG. 4C. In some embodiments, the second auxiliary IC 308b may include an RDL 904, and an additional array of terminals 906 may be formed on the RDL 904 and configured to electrically and/or thermally connect to a PCB substrate (not shown to avoid clutter, but see FIG. 3B).

One advantage of the configuration shown in FIG. 9B is that the first and second auxiliary ICs 308a, 308b optionally may be spaced apart by an air gap. An air gap may promote heat dissipation compared to a configuration in which the first and second auxiliary ICs 308a, 308b are in physical contact, and helps avoid any adverse influences between the first and second auxiliary ICs 308a, 308b (e.g., parasitic capacitance). In alternative embodiments, an intervening array of terminals (not shown, but see FIG. 8C) may be used to electrically and/or thermally couple the first and second auxiliary ICs 308a, 308b. Another advantage of the configuration shown in FIG. 9B is that optical inspection of the various arrays of terminals is still feasible.

The embodiments above may attach the auxiliary IC 308 (or a stack of auxiliary ICs 308) to the primary IC 302 during a BEOL fabrication process or a post-BEOL fabrication processes (e.g., OSAT). One method of attachment includes using a “pick and place” apparatus to remove an auxiliary IC 308 from a carrier (e.g., an adhesive tape) and placing that auxiliary IC 308 onto a primary IC 302, followed by a reflow process for permanent bonding.

Another method of attachment includes using a “pick and place” apparatus to remove an auxiliary IC 308 from a carrier and placing that auxiliary IC 308 onto a primary IC 302 mounted on a “reconstituted” wafer, followed by a reflow process for permanent bonding. A reconstituted wafer bears multiple singulated IC dies (generally tested to be “known good”) re-mounted on a carrier substrate. For example, the carrier substrate (e.g., glass or silicon) may have an adhesive layer (e.g., an epoxy compound) applied and then be populated with multiple known-good IC dies using, for example, a “pick and place” apparatus. Of course, which IC is mounted on a reconstituted wafer is relative; for example, multiple instances of the auxiliary IC 308 may be mounted on a substrate to as to form a reconstituted wafer and then primary ICs 302 may be “picked and placed” on corresponding auxiliary ICs 308.

The placement of an auxiliary IC 308 within the primary array of terminals 304 of a primary IC 302 may be selected to reduce the impact that the auxiliary IC 308 may have on high frequency (e.g., radio frequency) components within the primary IC 302.

Embodiments of the present invention may be used in a wide variety of applications. As one example, a multiple IC stack that includes a primary IC 302 with active circuitry (e.g., transistor switches) and at least one auxiliary IC 308 comprising one or more capacitors and/or one or more inductors may be particularly useful in compact power converters.

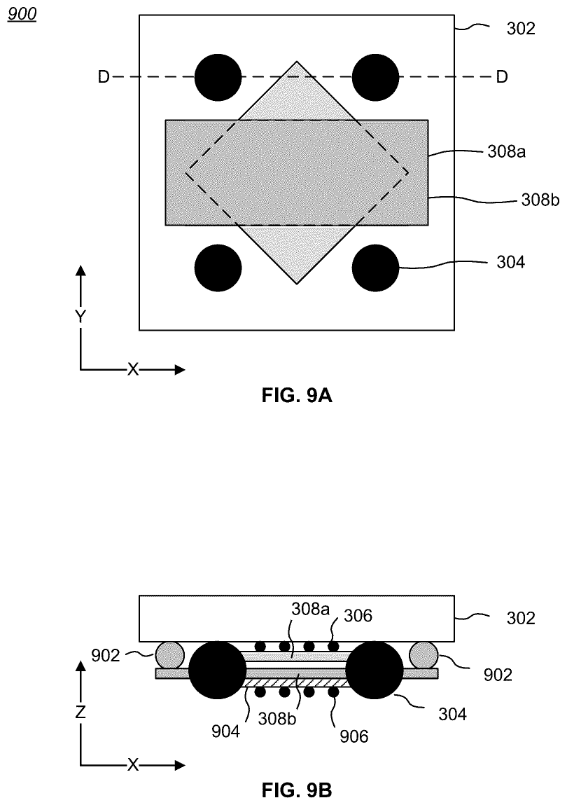

FIG. 10 is a schematic diagram of a prior art 3-level DC-to-DC buck converter circuit 1000. The illustrated converter circuit 1000 includes a “fly” capacitor C1 connected at node A between switches Sw1 and Sw2, and connected at node B between switches Sw3 and Sw4. Also included is an inductor L connected at node C between switches Sw2 and Sw3 and at node D to an output terminal V_{OUT_T}. An output capacitor C_{OUT} is coupled between node D and a reference potential (e.g., circuit ground) at node E. In the illustrated example, a voltage V_{IN} applied at an input terminal V_{IN_T} is converted to an output voltage V_{OUT}=/2V_{IN} at the output terminal V_{OUT_T}. Details of the operation of the converter circuit 1000 are set forth in U.S. patent application Ser. No. 17/560,767, filed Dec. 23, 2021, entitled “Controlling Charge-Balance and Transients in a Multi-Level Power Converter”, assigned to the assignee of the present invention and hereby incorporated by reference.

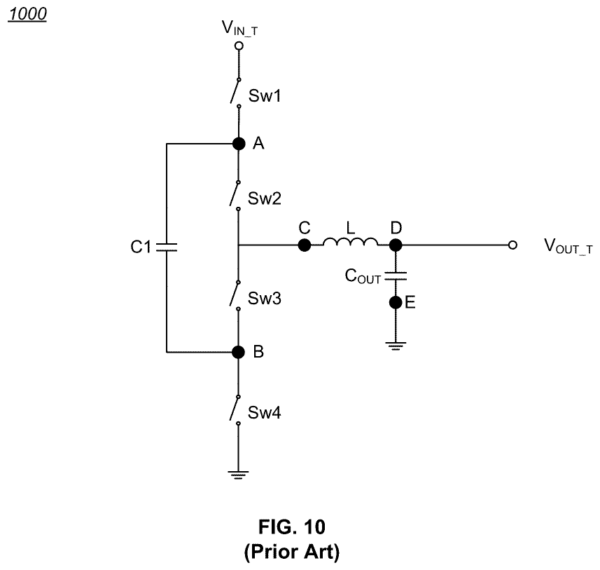

FIG. 11 is a bottom plan view of a first multiple IC stack 1100 with a stylized schematic circuit overlay representing in part the circuit of FIG. 10. Three of the terminals within the primary array of terminals 304 are configured to correspond to the input terminal V_{IN_T}, output terminal V_{OUT_T}, and circuit ground (GND). In the illustrated example, the auxiliary IC 308 embodies the fly capacitor C1 coupled between nodes A and B within the primary IC 302.

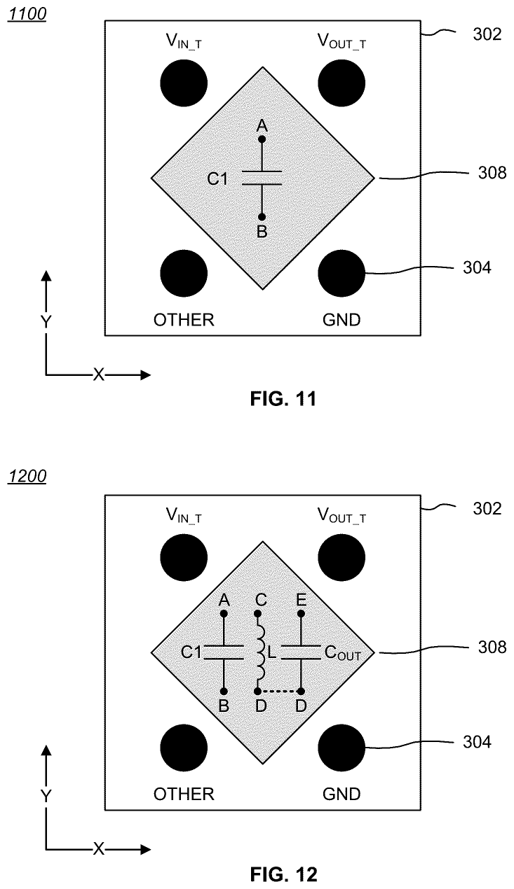

FIG. 12 is a bottom plan view of a second multiple IC stack 1200 with a stylized schematic circuit overlay representing in part the circuit of FIG. 10. Three of the terminals within the primary array of terminals 304 are configured to correspond to the input terminal V_{IN_T}, output terminal V_{OUT_T}, and circuit ground (GND). In the illustrated example, the auxiliary IC 308 embodies the fly capacitor C1 coupled between nodes A and B within the primary IC 302, the inductor L coupled between nodes C and D within the primary IC 302, and the output capacitor C_{OUT} coupled between nodes D and E within the primary IC 302. The dotted line between the two instances of node D indicates that the connection between the inductor L and capacitor C_{OUT} may be made within the auxiliary IC 308, thus saving a terminal within the auxiliary array of terminals 306 (see FIG. 3B) and further reducing parasitic capacitors and/or inductances.

It should be appreciated that an auxiliary IC 308 may include more than two capacitors or one inductor, and thus may support power converters that require more fly capacitors (e.g., divide-by-3, boost-by-2, boost-by-3, etc.) than the divide-by-2 converter circuit of FIG. 10.

It should also be appreciated that the auxiliary IC 308 in the examples of FIGS. 11 and 12 may comprise a stack of multiple auxiliary ICs 308, as in FIGS. 8A-8C. Such a stack allows for larger capacitance and/or inductance values, and/or a different allocation of capacitors and/or inductors to particular auxiliary ICs 308 within the stack.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

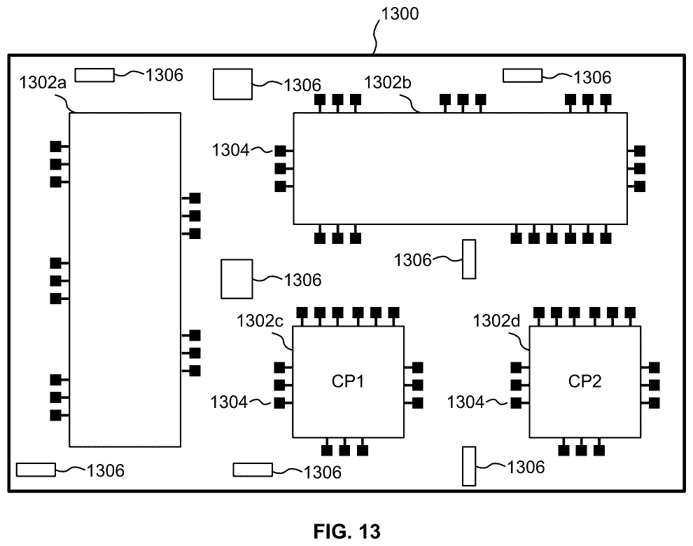

As one example of further integration of embodiments of the present invention with other components, FIG. 13 is a top plan view of a substrate 1300 that may be, for example, a printed circuit board or chip module substrate (e.g., a thin-film tile). In the illustrated example, the substrate 1300 includes multiple ICs 1302a-1302d having terminal pads 1304 which would be interconnected by conductive vias and/or traces on and/or within the substrate 1300 or on the opposite (back) surface of the substrate 1300 (to avoid clutter, the surface conductive traces are not shown and not all terminal pads are labelled). The ICs 1302a-1302d may embody, for example, signal switches, active and/or passive filters, amplifiers (including one or more LNAs), and other circuitry. For example, ICs 1302c and 1302d may comprise charge pumps CP1 and CP2, respectively, which each may comprise a multiple IC stack in accordance with the present invention. With suitable control circuitry, the outputs of the charge pumps CP1 and CP2 (or more, CP1 . . . CPn) may be coupled in parallel to provide a higher available power level.

The substrate 1300 may also include one or more passive devices 1306 embedded in, formed on, and/or affixed to the substrate 1300. While shown as generic rectangles, the passive devices 1306 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1300 to other passive devices 1306 and/or the individual ICs 1302a-1302d. The front or back surface of the substrate 1300 may be used as a location for the formation of other structures.

The multiple IC stack configurations may include a wide variety of combinations for the primary IC/auxiliary IC, including: processor/memory ICs, power FET/power FET ICs, power FET/gate driver ICs, and RF/antenna/filter ICs.

While the examples above have focused on the auxiliary IC 308 or stack of auxiliary ICs 308 comprising capacitors and/or inductors, it should be appreciated that the packaging concepts disclosed above apply to ICs that include, for example, analog and/or digital transistor circuitry, transmission lines, resistors, diodes, planar antennae elements, transducers (including, for example, MEMS-based transducers, such as accelerometers, gyroscopes, microphones, temperature sensors, humidity sensors, pressure sensors, etc.). The transistor circuitry may include, for example, vertical FETs, in which the source of a FET within an auxiliary IC 308 is proximate to the primary IC 302 while the drain of the FET is proximate to the other side of the auxiliary IC 308.

Embodiments of the present invention are useful in a wide variety of larger circuits and systems for performing a range of functions, including (but not limited to) impedance matching circuits, radio frequency (RF) power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G New Radio, 6G, and WiFi (e.g., 802.11a, b, g, ac, ax, be) protocols, as well as other radio communication standards and protocols.

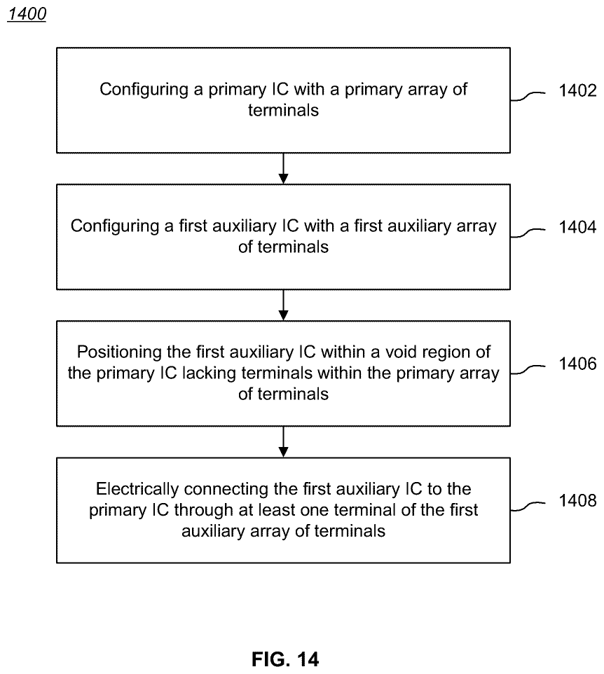

Another aspect of the invention includes methods for making a multiple integrated circuit (IC) stack. For example, FIG. 14 is a process flow chart 1400 showing one method for making a multiple IC stack. The method includes: configuring a primary IC with a primary array of terminals (Block 1402); configuring a first auxiliary IC with a first auxiliary array of terminals (Block 1404); positioning the first auxiliary IC within a void region of the primary IC lacking terminals within the primary array of terminals (Block 1406); and electrically connecting the first auxiliary IC to the primary IC through at least one terminal of the first auxiliary array of terminals (Block 1408).

Additional aspects of the above method may include one or more of the following: wherein the primary array of terminals are in a grid pattern, and the first auxiliary IC is rotated with respect to the grid pattern of the primary array of terminals; wherein the primary array of terminals are in a grid pattern, and the first auxiliary IC is rotated at about a 45° angle with respect to the grid pattern of the primary array of terminals; configuring a second auxiliary IC with a second auxiliary array of terminals, positioning the second auxiliary IC within the void region of the primary IC, and electrically connecting the second auxiliary IC to the primary IC through at least one terminal of the second auxiliary array of terminals; positioning a second auxiliary IC proximate to the first auxiliary IC in a sub-stack configuration; electrically connecting the second auxiliary IC to the first auxiliary IC through one or more through-substrate vias; electrically connecting the second auxiliary IC to the first auxiliary IC through an intervening array of terminals; electrically connecting the second auxiliary IC to the primary IC through an intervening array of terminals; wherein the second auxiliary IC is spaced apart from the first auxiliary IC; wherein the first auxiliary IC includes a redistribution layer, and further including providing an additional array of terminals connected to respective portions of the redistribution layer; configuring the primary array of terminals to mount the multiple IC stack on another structure; wherein the first auxiliary IC includes at least one capacitor; wherein the first auxiliary IC includes at least one inductor; wherein the first auxiliary IC includes at least one transistor circuit, and/or wherein the first auxiliary IC includes at least one of a transmission line, a resistor, a diode, an antenna element, or a transducer.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention may be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based power device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally may be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus may be performed in an order different from that described. Further, some of the steps described above may be optional. Various activities described with respect to the methods identified above may be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A multiple integrated circuit (IC) stack, including:
(a) a primary IC configured with a primary array of terminals; and
(b) a first auxiliary IC configured with a first auxiliary array of terminals and electrically connected to the primary IC through at least one terminal of the first auxiliary array of terminals, wherein the first auxiliary IC is positioned within a void region of the primary IC lacking terminals within the primary array of terminals.

2. The invention of claim 1, wherein the primary array of terminals are in a grid pattern, and the first auxiliary IC is rotated with respect to the grid pattern of the primary array of terminals.

3. The invention of claim 1, wherein the primary array of terminals are in a grid pattern, and the first auxiliary IC is rotated between about 30° and about 60° with respect to the grid pattern of the primary array of terminals.

4. The invention of claim 1, further including a second auxiliary IC configured with a second auxiliary array of terminals and electrically connected to the primary IC through at least one terminal of the second auxiliary array of terminals, wherein the second auxiliary IC is positioned within a void region of the primary IC lacking terminals within the primary array of terminals.

5. The invention of claim 1, further including a second auxiliary IC proximate to the first auxiliary IC in a sub-stack configuration.

6. The invention of claim 5, wherein the second auxiliary IC is electrically connected to the first auxiliary IC through one or more through-substrate vias.

7. The invention of claim 5, wherein the second auxiliary IC is electrically connected to the first auxiliary IC through an intervening array of terminals.

8. The invention of claim 5, wherein the second auxiliary IC is electrically connected to the primary IC through an intervening array of terminals.

9. The invention of claim 5, wherein the second auxiliary IC is spaced apart from the first auxiliary IC.

10. The invention of claim 1, wherein the first auxiliary IC includes a redistribution layer, and further including an additional array of terminals connected to respective portions of the redistribution layer.

11.-15. (canceled)

16. A multiple integrated circuit (IC) stack, including:
(a) a primary IC configured with a primary array of terminals; and
(b) a first auxiliary IC including at least one capacitor having a first and second terminal and configured with an auxiliary array of terminals, at least one terminal of the capacitor being electrically connected to the primary IC through at least one terminal of the auxiliary array of terminals, wherein the first auxiliary IC is positioned within a void region of the primary IC lacking terminals within the primary array of terminals.

17. The invention of claim 16, wherein the primary array of terminals are in a grid pattern, and the first auxiliary IC is rotated with respect to the grid pattern of the primary array of terminals.

18. The invention of claim 16, wherein the primary array of terminals are in a grid pattern, and the first auxiliary IC is rotated between about 30° and about 60° with respect to the grid pattern of the primary array of terminals.

19. The invention of claim 16, further including a second auxiliary IC configured with a second auxiliary array of terminals and electrically connected to the primary IC through at least one terminal of the second auxiliary array of terminals, wherein the second auxiliary IC is positioned within a void region of the primary IC lacking terminals within the primary array of terminals.

20. The invention of claim 16, further including a second auxiliary IC proximate to the first auxiliary IC in a sub-stack configuration.

21. The invention of claim 20, wherein the second auxiliary IC is electrically connected to the first auxiliary IC through one or more through-substrate vias.

22. The invention of claim 20, wherein the second auxiliary IC is electrically connected to the first auxiliary IC through an intervening array of terminals.

23. The invention of claim 20, wherein the second auxiliary IC is electrically connected to the primary IC through an intervening array of terminals.

24. The invention of claim 20, wherein the second auxiliary IC is spaced apart from the first auxiliary IC.

25. The invention of claim 16, wherein the first auxiliary IC includes a redistribution layer, and further including an additional array of terminals connected to respective portions of the redistribution layer.

26.-44. (canceled)
